(19) United States
(12) Patent Application Publication
(10) Pub. No.: US 2025/0355566 A1
(43) Pub. Date: Nov. 20, 2025

(54) MEMORY PERFORMANCE MANAGEMENT

(71) Applicant: Micron Technology, Inc., Boise, ID (US)

(72) Inventor: David Aaron Palmer, Boise, ID (US)

(21) Appl. No.: 19/195,336

(22) Filed: Apr. 30, 2025

Related U.S. Application Data
(60) Provisional application No. 63/649,834, filed on May 20, 2024.

(51) Int. Cl. G06F 3/06

(52) U.S. Cl. CPC G06F 3/0613; G06F 3/0659; G06F 3/0679

(57) ABSTRACT

Methods, systems, and devices for memory performance management are described. A memory system may limit performance, such as in accordance with a target data rate for the memory system. For example, the memory system may implement one or more timers. In response to receiving an access command, the memory system may initiate a timer, and may delay (e.g., suppress) performing other access commands until expiration of the timer. Additionally, or alternatively, the memory system may implement a credit-based approach to manage performance. For example, the memory system may periodically issue credits, such as by incrementing a counter. The memory system may consume credits to perform access commands. If the memory system receives a command to perform an access operation and does not have sufficient credits to perform the operation, the memory system may delay the operation, for example until sufficient credits are accrued.

### CROSS REFERENCE

The present application for patent claims priority to U.S. Patent Application No. 63/649,834 by Palmer, entitled “MEMORY PERFORMANCE MANAGEMENT,” filed May 20, 2024, which is assigned to the assignee hereof, and which is expressly incorporated by reference in its entirety herein.

### TECHNICAL FIELD

The following relates to one or more systems for memory, including memory performance management.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states if disconnected from an external power source.

### BRIEF DESCRIPTION OF THE DRAWINGS

FIG. 1 shows an example of a system that supports memory performance management in accordance with examples as disclosed herein.

FIG. 2 shows an example of a process that supports memory performance management in accordance with examples as disclosed herein.

FIG. 3 shows an example of a process that supports memory performance management in accordance with examples as disclosed herein.

FIG. 4 shows a block diagram of a memory system that supports memory performance management in accordance with examples as disclosed herein.

FIGS. 5 and 6 show flowcharts illustrating a method or methods that support memory performance management in accordance with examples as disclosed herein.

### DETAILED DESCRIPTION

As memory system technology improves over successive generations, costs associated with memory systems, such as manufacturing costs, research and development costs, and the like may increase. For example, as memory system capacity increases, the performance and cost of a memory system relative to the capacity of the memory system (e.g., the performance per gigabyte (GB) of the memory system, the cost per GB of the memory system) may also increase. However, memory system markets may expect improved performance at similar or reduced costs for successive generations. Further, performance and capacity improvements may not be linear across generations, which may increase complexity of product road-mapping. Additionally, increased performance of memory systems may result in consistently operating a memory system at a high data rate, which may lead to a premature end of device life, among other challenges. Accordingly, a memory system having one or more configurable performance characteristics may be desirable.

As described herein, a memory system may limit (e.g., throttle) performance, such as in accordance with a target data rate for the memory system. For example, the memory system may implement one or more timers. In response to or based on receiving a command (e.g., an access command), the memory system may initiate a timer, and may delay performing one or more other access commands until expiration of the timer. Additionally, or alternatively, the memory system may implement a credit-based approach to manage performance. For example, the memory system may periodically issue credits, such as by incrementing a counter. The memory system may consume credits (e.g., decrement the counter) if an access command is performed. If the memory system receives a command to perform an access operation and does not have sufficient credits to perform the operation, the memory system may delay the operation, for example until sufficient credits are accrued. Such techniques may support increased control of performance of the memory system, which may support improved market planning, and/or increase the lifetime of a memory system, among other benefits.

In addition to applicability in memory systems as described herein, techniques for memory performance management may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by managing performance in accordance with a target data rate, which may improve processing or latency times, improve response times, or otherwise improve user experience, among other benefits.

In addition to applicability in memory systems as described herein, techniques for memory performance management may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing the impact of consistently operating electronic devices at high data rates, which may extend the life of electronic devices and thereby reducing electronic waste, among other benefits.

Features of the disclosure are illustrated and described in the context of systems, devices, and circuits. Features of the disclosure are further illustrated and described in the context of processes and flowcharts.

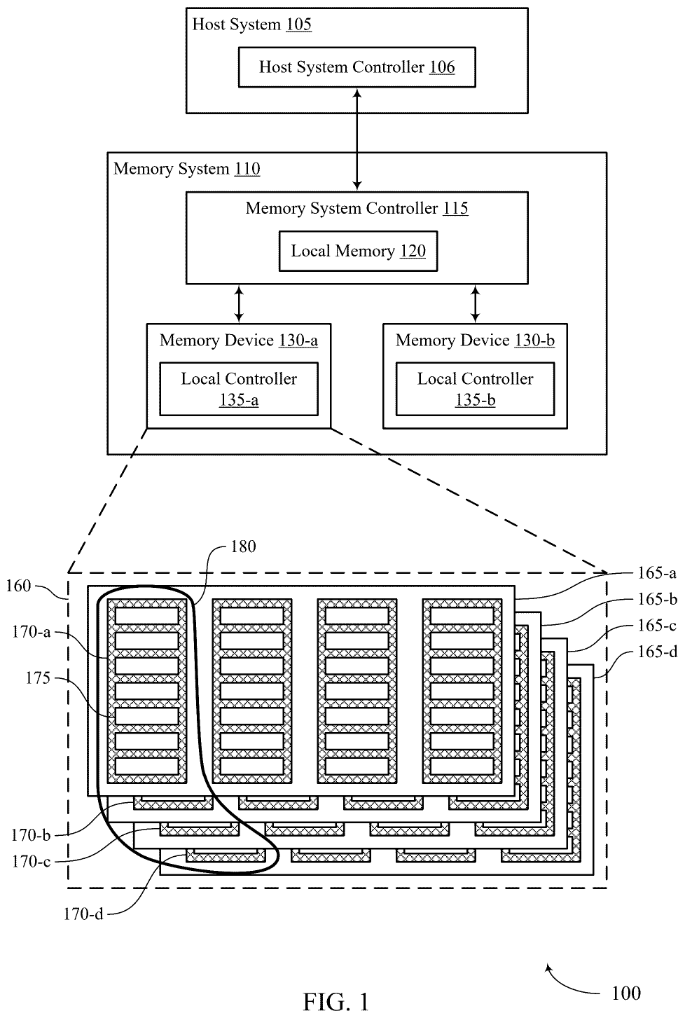

FIG. 1 shows an example of a system 100 that supports memory performance management in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with one or more host system controllers 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), one or more memory controllers (e.g., NVDIMM controller), and one or more storage protocol controllers (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between one or more host system controllers 106 of the host system 105 and one or more memory system controllers 115 of the memory system 110. In some examples, the host system 105 may be coupled with the memory system 110 (e.g., one or more host system controllers 106 may be coupled with one or more memory system controllers 115) via a respective physical host interface for each memory device 130 included in the memory system 110, or via a respective physical host interface for each type of memory device 130 included in the memory system 110.

The memory system 110 may include one or more memory system controllers 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including one or more memory system controllers 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) one or more local controllers 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize one or more memory system controllers 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The system 100 may include any quantity of non-transitory computer readable media that support memory performance management. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some cases, a memory system 110 may limit (e.g., throttle) performance, such as in accordance with a target data rate for the memory system 110. For example, the memory system 110 may implement one or more timers. In response to receiving a command (e.g., an access command), the memory system 110 may initiate a timer, and may delay performing other access commands until expiration of the timer. Additionally, or alternatively, the memory system 110 may implement a credit-based approach to manage performance. For example, the memory system 110 may periodically issue credits, such as by incrementing a counter. The memory system 110 may consume credits (e.g., decrement the counter) if an access command is performed. If the memory system 110 receives a command to perform an access operation and does not have sufficient credits to perform the operation, the memory system 110 may delay the operation, for example until sufficient credits are accrued. Such techniques may support increased control of performance of the memory system 110, which may support improved market planning, increase the lifetime of a memory system 110, or both, among other benefits.

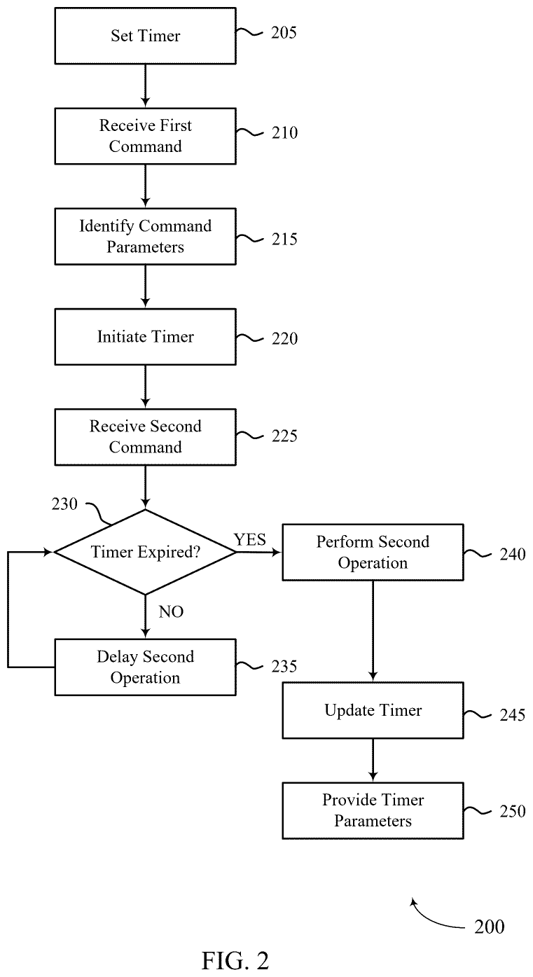

FIG. 2 shows an example of a process 200 that supports memory performance management in accordance with examples as disclosed herein. In some examples, a memory system, which may be an example of the memory system 110 as described with reference to FIG. 1, may implement aspects of the process 200 using one or more memory system controllers (e.g., a memory system controller 115). In the following description of process 200, the operations may be performed in a different order than the order shown. For example, specific operations may also be left out of process 200, or other operations may be added to process 200.

Aspects of the process 200 may be implemented by processing circuitry, such as one or more controllers, among other components. Additionally, or alternatively, aspects of the process 200 may be implemented as instructions stored in one or more memories (e.g., firmware stored in one or more memories, such as a memory device 130 or local memory 120 (or both), coupled with the memory system). For example, the instructions, when executed by one or more controllers (e.g., the memory system controller 115), may cause the one or more controllers (or a device or a system) to perform the operations of the process 200.

The process 200 may illustrate a method to implement one or more timers to manage performance of the memory system. For example, the memory system may use the timers to control a cadence at which various types of access operations are performed. In response to receiving an access command, for example an access command received from a host system, such as the host system 105 as described with reference to FIG. 1, the memory system may start (e.g., initiate) a timer of the one or more timers, and may initiate performing an access operation (e.g., a read operation, a write operation) corresponding to the access command. If the memory system receives a second access command subsequent to starting the timer, the memory system may determine whether timer has reached a threshold value (e.g., whether the timer has reached “0”, whether the timer has expired). If the memory system determines that the timer has reached the threshold value, the memory system may perform a second access operation corresponding to the second access command. Alternatively, if the timer has not reached the threshold value, the memory system may delay performing the second access operation until the timer has reached the threshold value.

In some cases, the memory system, the host system, or both may manage aspects of the one or more timers, such as an initial value of a timer, a type of access operation associated with a timer, a threshold associated with a timer, or a combination thereof. For example, at 205, a timer may be set with one or more initial parameters. In some cases, a host system may transmit a command to the memory system indicating the initial parameters. The command may be an example of a set features command, and the memory system may, in response to receiving the command, set the parameters of a timer indicated by the command.

The one or more parameters of the timers may include an initial value for the timer, a threshold associated with a timer, a type of access operation corresponding to a timer, a target data rate for the memory system, or a combination thereof. For example, if the one or more parameters indicate an initial value for a timer, the memory system may set the timer to the initial value. After initiating the timer, the timer may “run down” until timer expires (e.g., reaches a value of “0”). Additionally, or alternatively, if the one or more parameters indicates a threshold associated with a timer, the memory system may initially set the timer to a “0” value. After initiating the timer, the timer may “run up,” and if the timer exceeds the indicated threshold, the memory system may determine that the timer satisfies the indicated threshold.

In some examples, the memory system may manage the timers according to various granularities. For example, the memory system may maintain separate timers for each type of access operation (e.g., a first timer corresponding to read operations, a second timer corresponding to write operations), may maintain separate timers for different groups of memory cells (e.g., a respective timer for each block of memory cells, a respective timer for each plane of memory cells), or a combination thereof. In such examples, the memory system, the host system, or both may independently configure the parameters of each timer (e.g., using the set features command).

At 210, a first command associated with a first access operation may be received. In some examples, the first command may be a write command to write data to the memory system or a read command to read data from the memory system. For example, the memory system may receive the first access command from a host system, and may perform the first access operation.

At 215, one or more parameters of the first access command may be identified. The memory system may, for example, identify a size of data associated with the first access command (e.g., a size of data to be written, a size of data to be read), a type of the first access operation, a quantity of planes of the memory system associated with the first access operation, or a combination thereof. Based on the identified parameters, the memory system may determine (e.g., select, calculate) an initial value for the timer associated with the first access operation. For example, a relatively large size of data may correspond to commensurately long value for the timer, while a relatively small size of data may correspond to a short value for the timer. Additionally, or alternatively, the memory system may select a value for the timer to adjust the data rate of the memory system toward a target data rate.

At 220, the timer may be initiated. In some examples, the timer may be initiated in response to receiving the first access command (e.g., at 210), in response to identifying the one or more parameters (e.g., at 215), or both.

At 225, a second access command associated with a second access operation may be received. For example, the memory system may receive the second access command from the host system.

At 230, it may be determined whether the value of the timer satisfies a threshold. For example, the memory system may determine whether the value of the timer has expired (e.g., whether the value of the timer has reached a “0” value).

At 235, the second access command may be suppressed. For example, the memory system may suppress performing the second access command if the value of the timer does not satisfy the threshold. That is, the memory system may refrain from performing the second access command for a duration. For example, the memory system may store the second access command at a buffer or queue (e.g., a command queue managed by a memory system controller 115, as described with reference to FIG. 1). In some cases, the process may periodically return to 230, and the memory system may thus periodically determine whether the value of the timer satisfies the threshold.

At 240, the second access command may be performed. For example, after the expiration of the timer, the process may proceed to 240, and the memory system may perform the second access command Additionally, or alternatively, the expiration of the timer may act as trigger for the memory system to proceed to 240 and perform the second access command.

At 245, one or more parameters may be updated. In some examples, the one or more parameters of the timers may be updated. For example, the memory system may autonomously update (e.g., reset) the value of the timer, such as to the initial value. Additionally, the memory system may adjust or modify the initial value, for example by adjusting the initial value to modify the data rate of the memory system towards a target data rate. Additionally, or alternatively, the memory system may receive a command (e.g., a set features command) from a host system to modify the one or more parameters. In such examples, the command may include one or more values and field indicating values of the one or parameters, and the memory system may set the one or more parameters in accordance with the one or more values.

At 250, one or more parameters of the timers may be provided. For example, the host system may transmit a command, such as a get features command, requesting an indication of the one or more parameters, such as an indication of the initial value of a timer, an indication of the target data rate, an indication of a type of access operation associated with a timer, among other examples. In response to the command, the memory system may transmit one or more values indicating the one or more parameters to the host system. By managing the performance of the memory system using the one or more timers, the memory system may support increased control of performance of the memory system, which may support improved market planning, increase the lifetime of a memory system, or both, among other benefits.

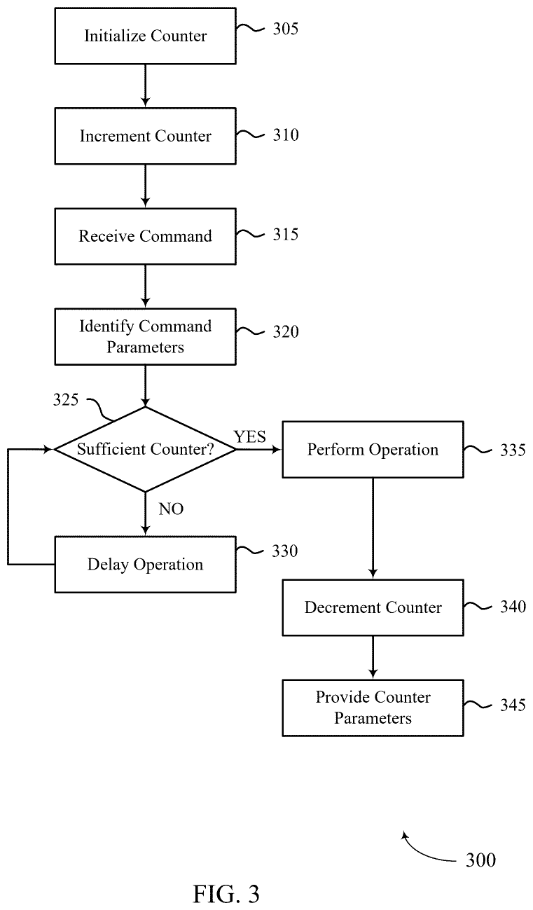

FIG. 3 shows an example of a process 300 that supports memory performance management in accordance with examples as disclosed herein. In some examples, a memory system, which may be an example of the memory system 110 as described with reference to FIG. 1, may implement aspects of the process 300 using one or more memory system controllers (e.g., a memory system controller 115). In the following description of process 300, the operations may be performed in a different order than the order shown. For example, specific operations may also be left out of process 300, or other operations may be added to process 300.

Aspects of the process 300 may be implemented by processing circuitry, such as one or more controllers, among other components. Additionally, or alternatively, aspects of the process 300 may be implemented as instructions stored in one or more memories (e.g., firmware stored in one or more memories, such as a memory device 130 or local memory 120 (or both), coupled with the memory system). For example, the instructions, when executed by one or more controllers (e.g., the memory system controller 115), may cause the one or more controllers (or a device or a system) to perform the operations of the process 300.

The process 300 may illustrate a method to implement a credit-based system using one or more counters to manage performance of the memory system. For example, the memory system may use the counters to control a cadence at which various types of access operations are performed. In response to receiving an access command, for example an access command from a host system, such as the host system 105 as described with reference to FIG. 1, the memory system may determine whether a value of a counter satisfies a threshold associated with the access operation corresponding to the access command (e.g., whether the counter indicates sufficient credits for the access operation). If the value of the counter satisfies the threshold, the memory system may perform the access operation. Alternatively, if the value of the counter does not satisfy the threshold, the memory system may delay performing the access operation until the counter has reached a sufficient value.

In some cases, the memory system, the host system, or both may manage aspects of the one or more counters, such as a period or frequency of incrementing the counter, an amount by which to increment the counter, a size or quantity of credits used for a particular type of access operation, a size or quantity of credits used for an amount of data associated with the access operation, an upper limit of the value of the counter, or a combination thereof.

At 305, the counter may be set with one or more initial parameters. In some cases, a host system may transmit a command to the memory system indicating the initial parameters. The command may be an example of a set features command, and the memory system may, in response to receiving the command, set the parameters of a counter indicated by the command.

The one or more parameters of the timers may include a period or frequency of incrementing the counter, an amount by which to increment the counter, a size or quantity of credits used for a particular type of access operation, a size or quantity of credits used for an amount of data associated with the access operation, an upper limit of the value of the counter, a target data rate for the memory system, or a combination thereof.

In some cases, the memory system may manage the counter according to various granularities. For example, the memory system may maintain separate counters for each type of access operation (e.g., a first counter corresponding to read operations, a second counter corresponding to write operations), may maintain separate counters for different groups of memory cells (e.g., a respective counter for each block of memory cells, a respective counter for each plane of memory cells), or a combination thereof. In such examples, the memory system, the host system, or both may independently configure the parameters of each counter (e.g., using the set features command).

At 310, the counter may be incremented (e.g., adjusted by a value of one, adjusted by a value of more than one). For example, the memory system may periodically add a value to the counter (e.g., issue one or more credits), such as by maintain a free-running timer. After expiration of the timer, the memory system may increment the counter and reset the timer. In some examples, the host system may modify the counter, such as by transmitting a command to reset the free-running timer and accordingly add a value to the counter. In some examples, the value of the counter may correspond to a positive integer, such that incrementing or increasing the value of the counter corresponds to adding one or more positive integers to the counter.

In some examples, the memory system may support an upper limit or threshold for the counter. For example, the memory system may determine whether the value of the counter is equal to or greater than the upper limit (or incrementing the counter would cause the value to exceed the upper limit). If the value of the counter is equal to or greater than the upper limit, the memory system may refrain from incrementing the counter.

At 315, a command associated with an access operation may be received (e.g., a write command to write data to the memory system, a read command to read data from the memory system). For example, the memory system may receive the command, such as an access command, from a host system, and may perform the first access operation based on the access command.

At 320, one or more parameters of the access command may be identified. The memory system may, for example, identify a size of data associated with the first access command (e.g., a size of data to be written, a size of data to be read), a type of the first access operation, a quantity of planes of the memory system associated with the first access operation, or a combination thereof. Based on the identified parameters, the memory system may determine (e.g., select, calculate) a value associated with the access operation (e.g., a “cost” of the access operation). For example, a relatively large size of data may correspond to commensurately large value, while a relatively small size of data may correspond to a small value. Additionally, or alternatively, the memory system may select a value to adjust the data rate of the memory system toward a target data rate.

At 325, it may be determined whether the value of the counter satisfies a threshold. For example, memory system may compare the value determined at 320 to the value of the counter.

At 330, the second access command may be suppressed. For example, if the value of the counter is less than the determined value, the memory system may suppress performing the access command. For example, the memory system may store the access command at a buffer or queue (e.g., a command queue managed by a memory system controller 115, as described with reference to FIG. 1). In some cases, the process 300 may periodically return to 325, and the memory system may thus periodically determine whether the value of the counter satisfies the threshold.

At 335, the access operation may be performed. For example, after the counter has accrued a sufficient value (e.g., a value greater than or equal to the determined value), the process 300 may proceed to 335 and the memory system may perform the access operation.

At 340, the counter may be decremented. For example, as part of or in response to performing the access operation, at 340, the counter may be decremented. In some examples, the memory system may reduce the value of the counter by the determined value.

At 345, one or more parameters of the counter may be provided. For example, the host system may transmit a command, such as a get features command, requesting an indication of the one or more parameters, such as a period or frequency of incrementing the counter, an amount by which to increment the counter, a size or quantity of credits used for a particular type of access operation, a size or quantity of credits used for an amount of data associated with the access operation, an upper limit of the value of the counter, a target data rate for the memory system, or a combination thereof, among other examples. In response to the command, the memory system may transmit one or more values indicating the one or more parameters to the host system. By managing the performance of the memory system using the counter, the memory system may support increased control of performance of the memory system, which may support improved market planning, increase the lifetime of a memory system, or both, among other benefits.

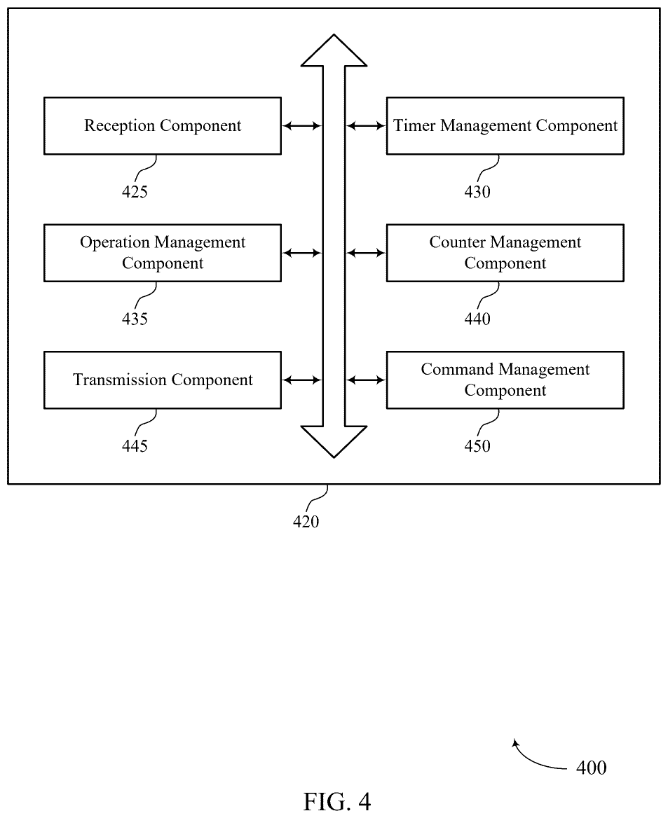

FIG. 4 shows a block diagram 400 of a memory system 420 that supports memory performance management in accordance with examples as disclosed herein. The memory system 420 may be an example of aspects of a memory system as described with reference to FIGS. 1 through 3. The memory system 420, or various components thereof, may be an example of means for performing various aspects of memory performance management as described herein. For example, the memory system 420 may include a reception component 425, a timer management component 430, an operation management component 435, a counter management component 440, a transmission component 445, a command management component 450, or any combination thereof. Each of these components, or components of subcomponents thereof (e.g., one or more processors, one or more memories), may communicate, directly or indirectly, with one another (e.g., via one or more buses).

The reception component 425 may be configured as or otherwise support a means for receiving a first command associated with a first access operation. The timer management component 430 may be configured as or otherwise support a means for initiating a timer based at least in part on receiving the first command. In some examples, the reception component 425 may be configured as or otherwise support a means for receiving a second command associated with a second access operation. The operation management component 435 may be configured as or otherwise support a means for suppressing performing the second access operation based at least in part on a value of timer satisfying a threshold value.

In some examples, the reception component 425 may be configured as or otherwise support a means for receiving a third command including an indication of an initial value of the timer. In some examples, the timer management component 430 may be configured as or otherwise support a means for setting the initial value of the timer based at least in part on receiving the third command.

In some examples, the reception component 425 may be configured as or otherwise support a means for receiving a fourth command including an updated initial value of the timer. In some examples, the timer management component 430 may be configured as or otherwise support a means for updating the initial value of the timer based at least in part on receiving the fourth command.

In some examples, the reception component 425 may be configured as or otherwise support a means for receiving a fifth command including a request for an initial value of the timer. In some examples, the transmission component 445 may be configured as or otherwise support a means for transmitting an indication of an initial value of the timer based at least in part on receiving the fifth command.

In some examples, the operation management component 435 may be configured as or otherwise support a means for performing the second access operation based at least in part on the value of the timer failing to satisfy the threshold value.

In some examples, the command management component 450 may be configured as or otherwise support a means for identifying one or more parameters associated with the first command. In some examples, the timer management component 430 may be configured as or otherwise support a means for selecting an initial value for the timer based at least in part on the one or more parameters, where the timer includes the initial value when initiated.

In some examples, the one or more parameters include a size of data associated with the first access operation, a type of the first access operation, a quantity of planes of the memory system associated with the first access operation, or a combination thereof.

In some examples, the command management component 450 may be configured as or otherwise support a means for determining, by the memory system, a target rate for processing commands. In some examples, the timer management component 430 may be configured as or otherwise support a means for selecting an initial value for the timer based at least in part on the target rate, where the timer includes the initial value when initiated.

In some examples, the operation management component 435 may be configured as or otherwise support a means for performing the first access operation based at least in part on receiving the first command, where initiating the timer is based at least in part on performing the first access operation.

In some examples, the value of the timer failing to satisfy the threshold value corresponds to the value of the timer expiring.

The counter management component 440 may be configured as or otherwise support a means for incrementing a value of counter of the memory system, where the value of the counter is associated with performing access operations at the memory system. In some examples, the reception component 425 may be configured as or otherwise support a means for receiving a first command associated with a first access operation based at least in part on incrementing the value of the counter. In some examples, the operation management component 435 may be configured as or otherwise support a means for performing the first access operation based at least in part on the value of the counter satisfying a first threshold value. In some examples, the counter management component 440 may be configured as or otherwise support a means for adjusting the value of the counter based at least in part on performing the first access operation.

In some examples, the reception component 425 may be configured as or otherwise support a means for receiving a second command associated with a second access operation based at least in part on adjusting the value of the counter. In some examples, the operation management component 435 may be configured as or otherwise support a means for refraining from performing the second access operation based at least in part on the value of the counter failing to satisfy the first threshold value.

In some examples, when the value of the counter satisfies the first threshold value, the value of the counter includes a positive integer.

In some examples, the counter management component 440 may be configured as or otherwise support a means for determining that the value of the counter satisfies a second threshold value. In some examples, the counter management component 440 may be configured as or otherwise support a means for refraining from incrementing the value of the counter based at least in part on determining that the value of the counter satisfies the second threshold value.

In some examples, the reception component 425 may be configured as or otherwise support a means for receiving a third command including an indication of an initial value of the counter. In some examples, the counter management component 440 may be configured as or otherwise support a means for setting the initial value of the counter based at least in part on receiving the third command.

In some examples, the command management component 450 may be configured as or otherwise support a means for identifying one or more parameters associated with the first command. In some examples, the counter management component 440 may be configured as or otherwise support a means for determining a quantity of values to adjust the counter based at least in part on the one or more parameters, where the counter is adjusted based at least in part on the determined quantity of values.

In some examples, the one or more parameters include a size of data associated with the first access operation, a type of the first access operation, a quantity of planes of the memory system associated with the first access operation, or a combination thereof.

In some examples, the command management component 450 may be configured as or otherwise support a means for determining, by the memory system, a target rate for processing commands. In some examples, the counter management component 440 may be configured as or otherwise support a means for determining a quantity of values to adjust the counter based at least in part on the target rate, where the counter is adjusted based at least in part on the determined quantity of values.

In some examples, the value of the counter is incremented at a fixed interval.

In some examples, to support adjusting the value of the counter, the counter management component 440 may be configured as or otherwise support a means for decrementing the value of the counter.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

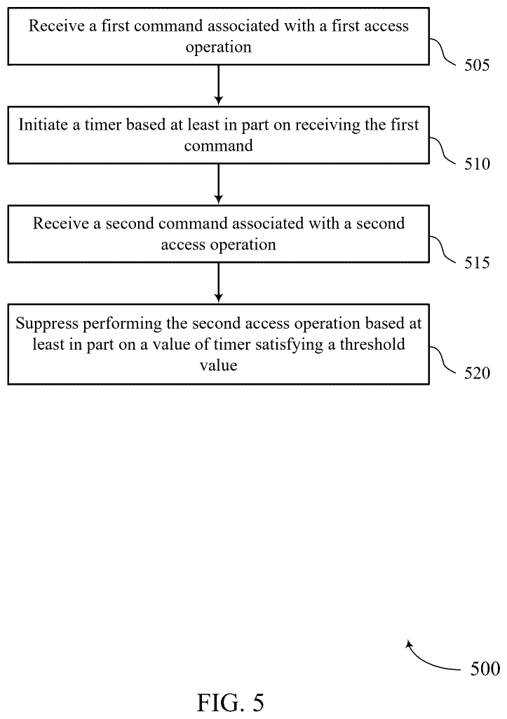

FIG. 5 shows a flowchart illustrating a method 500 that supports memory performance management in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include receiving a first command associated with a first access operation. In some examples, aspects of the operations of 505 may be performed by a reception component 425 as described with reference to FIG. 4.

At 510, the method may include initiating a timer based at least in part on receiving the first command. In some examples, aspects of the operations of 510 may be performed by a timer management component 430 as described with reference to FIG. 4.

At 515, the method may include receiving a second command associated with a second access operation. In some examples, aspects of the operations of 515 may be performed by a reception component 425 as described with reference to FIG. 4.

At 520, the method may include suppressing performing the second access operation based at least in part on a value of timer satisfying a threshold value. In some examples, aspects of the operations of 520 may be performed by an operation management component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a first command associated with a first access operation; initiating a timer based at least in part on receiving the first command; receiving a second command associated with a second access operation; and suppressing performing the second access operation based at least in part on a value of timer satisfying a threshold value.

Aspect 2: The method, apparatus, or non-transitory computer-readable medium of aspect 1, further including operations, features, circuitry, logic, means, or instructions, or any combination thereof for receiving a third command including an indication of an initial value of the timer and setting the initial value of the timer based at least in part on receiving the third command.

Aspect 3: The method, apparatus, or non-transitory computer-readable medium of aspect 2, further including operations, features, circuitry, logic, means, or instructions, or any combination thereof for receiving a fourth command including an updated initial value of the timer and updating the initial value of the timer based at least in part on receiving the fourth command.

Aspect 4: The method, apparatus, or non-transitory computer-readable medium of any of aspects 1 through 3, further including operations, features, circuitry, logic, means, or instructions, or any combination thereof for receiving a fifth command including a request for an initial value of the timer and transmitting an indication of an initial value of the timer based at least in part on receiving the fifth command.

Aspect 5: The method, apparatus, or non-transitory computer-readable medium of any of aspects 1 through 4, further including operations, features, circuitry, logic, means, or instructions, or any combination thereof for performing the second access operation based at least in part on the value of the timer failing to satisfy the threshold value.

Aspect 6: The method, apparatus, or non-transitory computer-readable medium of any of aspects 1 through 5, further including operations, features, circuitry, logic, means, or instructions, or any combination thereof for identifying one or more parameters associated with the first command and selecting an initial value for the timer based at least in part on the one or more parameters, where the timer includes the initial value when initiated.

Aspect 7: The method, apparatus, or non-transitory computer-readable medium of aspect 6, where the one or more parameters include a size of data associated with the first access operation, a type of the first access operation, a quantity of planes of the memory system associated with the first access operation, or a combination thereof.

Aspect 8: The method, apparatus, or non-transitory computer-readable medium of any of aspects 1 through 7, further including operations, features, circuitry, logic, means, or instructions, or any combination thereof for determining, by the memory system, a target rate for processing commands and selecting an initial value for the timer based at least in part on the target rate, where the timer includes the initial value when initiated.

Aspect 9: The method, apparatus, or non-transitory computer-readable medium of any of aspects 1 through 8, further including operations, features, circuitry, logic, means, or instructions, or any combination thereof for performing the first access operation based at least in part on receiving the first command, where initiating the timer is based at least in part on performing the first access operation.

Aspect 10: The method, apparatus, or non-transitory computer-readable medium of any of aspects 1 through 9, where the value of the timer failing to satisfy the threshold value corresponds to the value of the timer expiring.

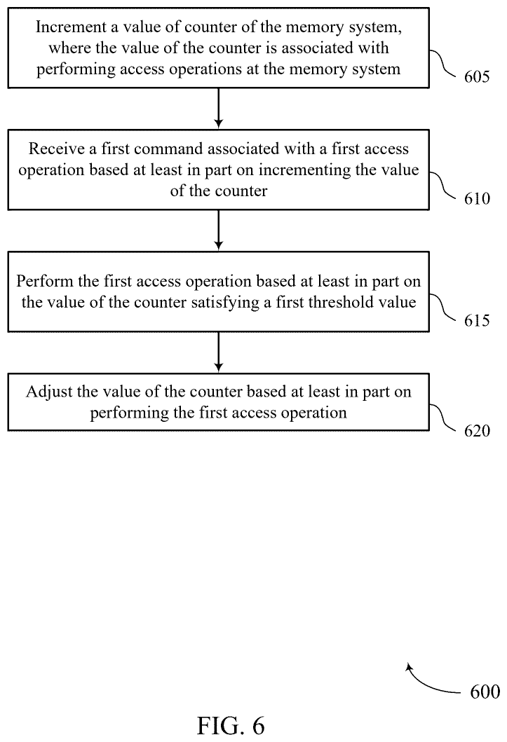

FIG. 6 shows a flowchart illustrating a method 600 that supports memory performance management in accordance with examples as disclosed herein. The operations of method 600 may be implemented by a memory system or its components as described herein. For example, the operations of method 600 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 605, the method may include incrementing a value of counter of the memory system, where the value of the counter is associated with performing access operations at the memory system. In some examples, aspects of the operations of 605 may be performed by a counter management component 440 as described with reference to FIG. 4.

At 610, the method may include receiving a first command associated with a first access operation based at least in part on incrementing the value of the counter. In some examples, aspects of the operations of 610 may be performed by a reception component 425 as described with reference to FIG. 4.

At 615, the method may include performing the first access operation based at least in part on the value of the counter satisfying a first threshold value. In some examples, aspects of the operations of 615 may be performed by an operation management component 435 as described with reference to FIG. 4.

At 620, the method may include adjusting the value of the counter based at least in part on performing the first access operation. In some examples, aspects of the operations of 620 may be performed by a counter management component 440 as described with reference to FIG. 4.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 11: A method, apparatus, or non-transitory computer-readable medium including operations, features, circuitry, logic, means, or instructions, or any combination thereof for incrementing a value of counter of the memory system, where the value of the counter is associated with performing access operations at the memory system; receiving a first command associated with a first access operation based at least in part on incrementing the value of the counter; performing the first access operation based at least in part on the value of the counter satisfying a first threshold value; and adjusting the value of the counter based at least in part on performing the first access operation.

Aspect 12: The method, apparatus, or non-transitory computer-readable medium of aspect 11, further including operations, features, circuitry, logic, means, or instructions, or any combination thereof for receiving a second command associated with a second access operation based at least in part on adjusting the value of the counter and refraining from performing the second access operation based at least in part on the value of the counter failing to satisfy the first threshold value.

Aspect 13: The method, apparatus, or non-transitory computer-readable medium of any of aspects 11 through 12, where when the value of the counter satisfies the first threshold value, the value of the counter includes a positive integer.

Aspect 14: The method, apparatus, or non-transitory computer-readable medium of any of aspects 11 through 13, further including operations, features, circuitry, logic, means, or instructions, or any combination thereof for determining that the value of the counter satisfies a second threshold value and refraining from incrementing the value of the counter based at least in part on determining that the value of the counter satisfies the second threshold value.

Aspect 15: The method, apparatus, or non-transitory computer-readable medium of any of aspects 11 through 14, further including operations, features, circuitry, logic, means, or instructions, or any combination thereof for receiving a third command including an indication of an initial value of the counter and setting the initial value of the counter based at least in part on receiving the third command.

Aspect 16: The method, apparatus, or non-transitory computer-readable medium of any of aspects 11 through 15, further including operations, features, circuitry, logic, means, or instructions, or any combination thereof for identifying one or more parameters associated with the first command and determining a quantity of values to adjust the counter based at least in part on the one or more parameters, where the counter is adjusted based at least in part on the determined quantity of values.

Aspect 17: The method, apparatus, or non-transitory computer-readable medium of aspect 16, where the one or more parameters include a size of data associated with the first access operation, a type of the first access operation, a quantity of planes of the memory system associated with the first access operation, or a combination thereof.

Aspect 18: The method, apparatus, or non-transitory computer-readable medium of any of aspects 11 through 17, further including operations, features, circuitry, logic, means, or instructions, or any combination thereof for determining, by the memory system, a target rate for processing commands and determining a quantity of values to adjust the counter based at least in part on the target rate, where the counter is adjusted based at least in part on the determined quantity of values.

Aspect 19: The method, apparatus, or non-transitory computer-readable medium of any of aspects 11 through 18, where the value of the counter is incremented at a fixed interval.

Aspect 20: The method, apparatus, or non-transitory computer-readable medium of any of aspects 11 through 19, where adjusting the value of the counter includes operations, features, circuitry, logic, means, or instructions, or any combination thereof for decrementing the value of the counter.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
receive a first command associated with a first access operation;
initiate a timer based at least in part on receiving the first command;
receive a second command associated with a second access operation; and
suppress performing the second access operation based at least in part on a value of timer satisfying a threshold value.

2. The memory system of claim 1, wherein the processing circuitry is further configured to cause the memory system to:
receive a third command comprising an indication of an initial value of the timer; and
set the initial value of the timer based at least in part on receiving the third command.

3. The memory system of claim 2, wherein the processing circuitry is further configured to cause the memory system to:
receive a fourth command comprising an updated initial value of the timer; and
update the initial value of the timer based at least in part on receiving the fourth command.

4. The memory system of claim 1, wherein the processing circuitry is further configured to cause the memory system to:
receive a fifth command comprising a request for an initial value of the timer; and
transmit an indication of an initial value of the timer based at least in part on receiving the fifth command.

5. The memory system of claim 1, wherein the processing circuitry is further configured to cause the memory system to:
perform the second access operation based at least in part on the value of the timer failing to satisfy the threshold value.

6. The memory system of claim 1, wherein the processing circuitry is further configured to cause the memory system to:
identify one or more parameters associated with the first command; and
select an initial value for the timer based at least in part on the one or more parameters, wherein the timer comprises the initial value when initiated.

7. The memory system of claim 6, wherein the one or more parameters comprise a size of data associated with the first access operation, a type of the first access operation, a quantity of planes of the memory system associated with the first access operation, or a combination thereof.

8. The memory system of claim 1, wherein the processing circuitry is further configured to cause the memory system to:
determine, by the memory system, a target rate for processing commands; and
select an initial value for the timer based at least in part on the target rate, wherein the timer comprises the initial value when initiated.

9. The memory system of claim 1, wherein the processing circuitry is further configured to cause the memory system to:
perform the first access operation based at least in part on receiving the first command, wherein initiating the timer is based at least in part on performing the first access operation.

10. The memory system of claim 1, wherein the value of the timer failing to satisfy the threshold value corresponds to the value of the timer expiring.

11. A memory system, comprising:
one or more memory devices; and
processing circuitry coupled with the one or more memory devices and configured to cause the memory system to:
increment a value of counter of the memory system, wherein the value of the counter is associated with performing access operations at the memory system;
receive a first command associated with a first access operation based at least in part on incrementing the value of the counter;
perform the first access operation based at least in part on the value of the counter satisfying a first threshold value; and
adjust the value of the counter based at least in part on performing the first access operation.

12. The memory system of claim 11, wherein the processing circuitry is further configured to cause the memory system to:
receive a second command associated with a second access operation based at least in part on adjusting the value of the counter; and
refrain from performing the second access operation based at least in part on the value of the counter failing to satisfy the first threshold value.

13. The memory system of claim 11, wherein when the value of the counter satisfies the first threshold value, the value of the counter comprises a positive integer.

14. The memory system of claim 11, wherein the processing circuitry is further configured to cause the memory system to:
determine that the value of the counter satisfies a second threshold value; and
refrain from incrementing the value of the counter based at least in part on determining that the value of the counter satisfies the second threshold value.

15. The memory system of claim 11, wherein the processing circuitry is further configured to cause the memory system to:
receive a third command comprising an indication of an initial value of the counter; and
set the initial value of the counter based at least in part on receiving the third command.

16. The memory system of claim 11, wherein the processing circuitry is further configured to cause the memory system to:
identify one or more parameters associated with the first command; and
determine a quantity of values to adjust the counter based at least in part on the one or more parameters, wherein the counter is adjusted based at least in part on the determined quantity of values.

17. The memory system of claim 16, wherein the one or more parameters comprise a size of data associated with the first access operation, a type of the first access operation, a quantity of planes of the memory system associated with the first access operation, or a combination thereof.

18. The memory system of claim 11, wherein the processing circuitry is further configured to cause the memory system to:
determine, by the memory system, a target rate for processing commands; and
determine a quantity of values to adjust the counter based at least in part on the target rate, wherein the counter is adjusted based at least in part on the determined quantity of values.

19. The memory system of claim 11, wherein the value of the counter is incremented at a fixed interval.

20. The memory system of claim 11, wherein adjusting the value of the counter comprises the processing circuitry configured to cause the memory system to:
decrement the value of the counter.

21. A non-transitory computer-readable medium storing code comprising instructions which, when executed by one or more processors of a memory system, cause the memory system to:
receive a first command associated with a first access operation;
initiate a timer based at least in part on receiving the first command;
receive a second command associated with a second access operation; and
suppress performing the second access operation based at least in part on a value of timer satisfying a threshold value.

22. The non-transitory computer-readable medium of claim 21, wherein the instructions, when executed by the one or more processors of the memory system, further cause the memory system to:
receive a third command comprising an indication of an initial value of the timer; and
set the initial value of the timer based at least in part on receiving the third command.

23. The non-transitory computer-readable medium of claim 22, wherein the instructions, when executed by the one or more processors of the memory system, further cause the memory system to:
receive a fourth command comprising an updated initial value of the timer; and
update the initial value of the timer based at least in part on receiving the fourth command.

24. The non-transitory computer-readable medium of claim 21, wherein the instructions, when executed by the one or more processors of the memory system, further cause the memory system to:
receive a fifth command comprising a request for an initial value of the timer; and
transmit an indication of an initial value of the timer based at least in part on receiving the fifth command.

25. The non-transitory computer-readable medium of claim 21, wherein the instructions, when executed by the one or more processors of the memory system, further cause the memory system to:
perform the second access operation based at least in part on the value of the timer failing to satisfy the threshold value.
